(19) United States
(12) Patent Application Publication
(10) Pub. No.: US 2012/0153352 A1
(43) Pub. Date: Jun. 21, 2012

(54) HIGH INDIUM CONTENT TRANSISTOR CHANNELS

(76) Inventors: Gilbert Dewey, Hillsboro, OR (US); Niloy Mukherjee, Beaverton, OR (US); Marko Radosavljevic, Beaverton, OR (US); Benjamin Chu-Kung, Hillsboro, OR (US)

(21) Appl. No.: 12/968,905

(22) Filed: Dec. 15, 2010

(51) Int. Cl. H01L 29/778

(52) U.S. Cl. 257/192; 257/E29.246

(57) ABSTRACT

The present disclosure relates to the field of microelectronic transistor fabrication and, more particularly, to the formation of high mobility transistor channels from high indium content alloys, wherein the high indium content transistor channels are achieved with a barrier layer that can substantially lattice match with the high indium content transistor channel.

### BACKGROUND

Embodiments of the present description generally relate to the field of microelectronic transistor fabrication and, more particularly, to the formation of high mobility transistor channels.

### BRIEF DESCRIPTION OF THE DRAWINGS

The subject matter of the present disclosure is particularly pointed out and distinctly claimed in the concluding portion of the specification. The foregoing and other features of the present disclosure will become more fully apparent from the following description and appended claims, taken in conjunction with the accompanying drawings. It is understood that the accompanying drawings depict only several embodiments in accordance with the present disclosure and are, therefore, not to be considered limiting of its scope. The disclosure will be described with additional specificity and detail through use of the accompanying drawings, such that the advantages of the present disclosure can be more readily ascertained, in which:

FIG. 1 illustrates a side cross-sectional view of a substrate having a buffer layer formed thereon, a barrier layer formed on the buffer layer, and a transistor channel material formed on the barrier layer.

FIG. 2 illustrates the structure of FIG. 1, wherein the transistor channel material has been etched to form a transistor channel.

FIG. 3 is a graph of alloys of differing indium content plotted against Hall mobility.

FIG. 4 is a graph illustrating a grading path for one embodiment of the present description.

FIG. 5 illustrates a multi-layered barrier layer according to one embodiment of the present description.

FIG. 6 illustrates a multi-layered barrier layer having non-linear grading according to another embodiment of the present description.

FIG. 7 illustrates a barrier layer according to still another embodiment of the present description.

FIG. 8 illustrates a barrier layer having non-linear grading according to another embodiment of the present description.

FIG. 9 illustrates non-planar transistors having a high indium content transistor channel with the lattice matched barrier layer of the present description.

FIG. 10 illustrates an embodiment of a portable electronic device.

FIG. 11 illustrates an embodiment of a computer system.

FIG. 12 is a block diagram of an electronic system.

### DETAILED DESCRIPTION

In the following detailed description, reference is made to the accompanying drawings that show, by way of illustration, specific embodiments in which the claimed subject matter may be practiced. These embodiments are described in sufficient detail to enable those skilled in the art to practice the subject matter. It is to be understood that the various embodiments, although different, are not necessarily mutually exclusive. For example, a particular feature, structure, or characteristic described herein, in connection with one embodiment, may be implemented within other embodiments without departing from the spirit and scope of the claimed subject matter. In addition, it is to be understood that the location or arrangement of individual elements within each disclosed embodiment may be modified without departing from the spirit and scope of the claimed subject matter. The following detailed description is, therefore, not to be taken in a limiting sense, and the scope of the subject matter is defined only by the appended claims, appropriately interpreted, along with the full range of equivalents to which the appended claims are entitled. In the drawings, like numerals refer to the same or similar elements or functionality throughout the several views, and that elements depicted therein are not necessarily to scale with one another, rather individual elements may be enlarged or reduced in order to more easily comprehend the elements in the context of the present description.

Embodiments of the present description generally relate to the field of microelectronic transistor fabrication and, more particularly, to the formation of high mobility transistor channels from high indium content alloys, wherein the high indium content transistor channels are achieved with a barrier layer that can substantially lattice match with the high indium content transistor channel.

In the fabrication of non-planar transistors, such as tri-gate transistors, FinFETs, omega-FETs, quantum well transistors, and double-gate transistors, non-planar transistor channels may be used to form transistors capable of full depletion with very small gate lengths (e.g., less than about 30 nm). For example in a tri-gate transistor, the transistor channels generally have a fin-shape with a top surface and two opposing sidewalls formed on a bulk semiconductor substrate or a silicon-on-insulator substrate. A gate dielectric may be formed on the top surface and sidewalls of the transistor channel and a gate electrode may be formed over the gate dielectric on the top surface of the transistor channel and adjacent to the gate dielectric on the sidewalls of the transistor channel. Thus, since the gate dielectric and the gate electrode are adjacent to three surfaces of the transistor channel, three separate channels and gates are formed. As there are three separate channels formed, the transistor channel can be fully depleted when the transistor is turned on.

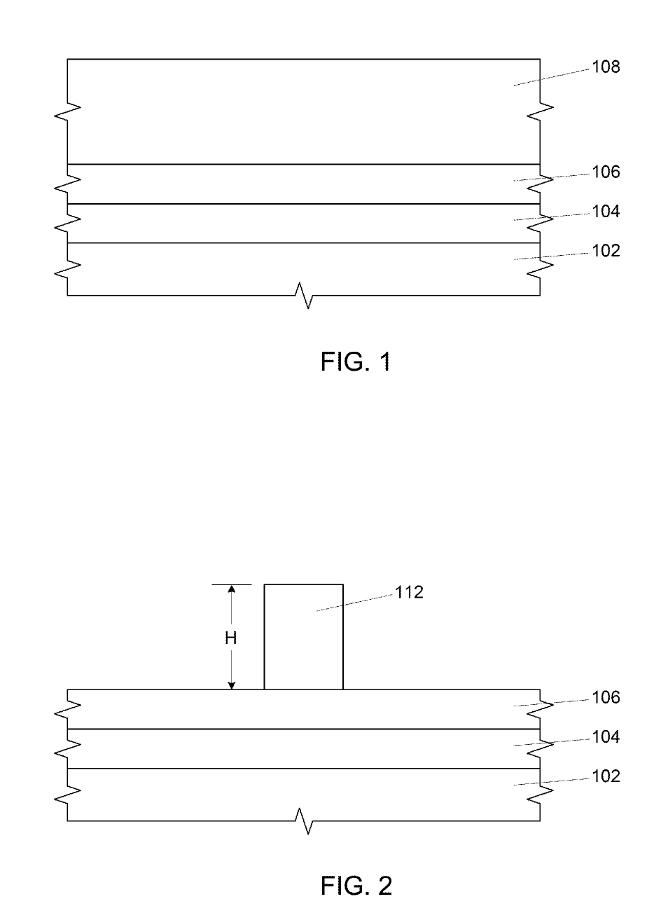

FIGS. 1 and 2 illustrate the formation of a transistor channel. As shown in FIG. 1, a substrate 102 may be provided with a buffer layer 104 formed on the substrate 102. A barrier layer 106 may be formed over the buffer layer 104 and a transistor channel material layer 108 may be formed on the buffer layer 104. The transistor channel material layer 108 may be etched, such as by lithographic techniques, to form a transistor channel 112, as shown in FIG. 2. The buffer layer 104 is used to grade away the lattice mismatch from the substrate 102 to barrier layer 106, and the barrier layer 104 is used to grade away the lattice mismatch for the barrier layer 104 to the transistor channel 112, as will be discussed.

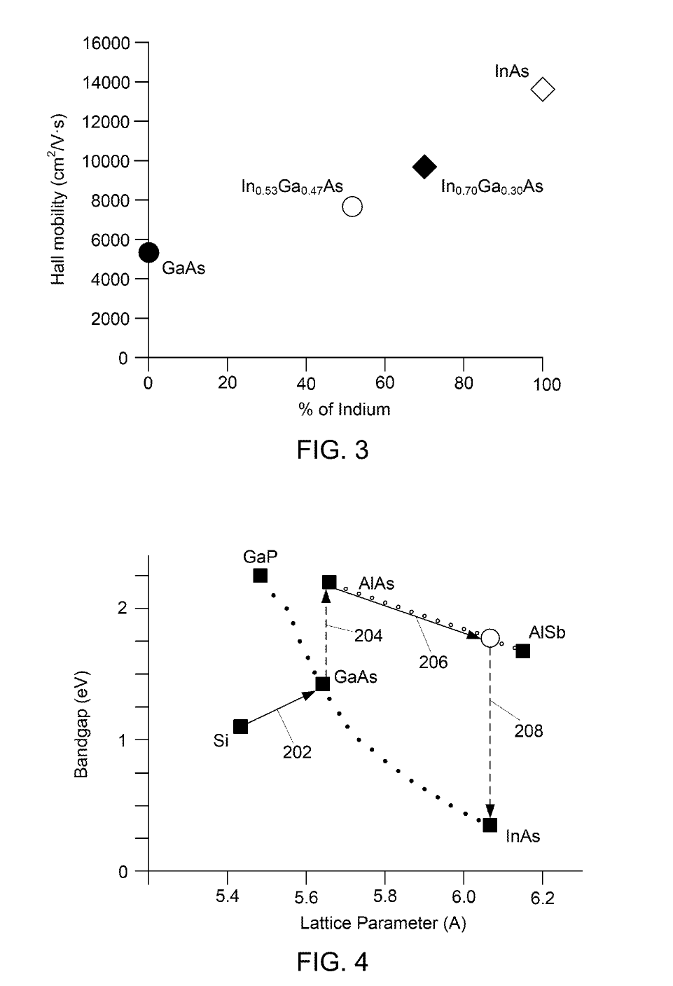

As is understood to those skilled in the art, there is a continuing drive to increase the channel mobility of transistor channels 112, as an increase in channel mobility can result in advantages, including but not limit to, reduced electrical resistance, improved efficiency, increased current, and increased speed. In the pursuit of increased channel mobility, transistor channels 112 are being formed from Group III-V elements. In a known embodiment, the transistor channel 112 may comprise an alloy of indium (In), gallium (Ga), and arsenic (As), such as In_{0.53}Ga_{0.47}As. It is has been found that increasing the indium content in the transistor channel 112 increases mobility. This is demonstrated in FIG. 3, where alloys of different indium content are plotted by their Hall mobility. The black circle corresponds to GaAs (i.e., no indium). The white circle corresponds to In_{0.53}Ga_{0.47}As. The black diamond corresponds to In_{0.70}Ga_{0.30}As. The white diamond corresponds to InAs.

Although increasing the indium content may appear to be a path forward for higher channel mobility, it is currently not practical for non-planar transistor channels on known barrier layers (e.g., such as an InAlAs barrier layers for In_{0.53}Ga_{0.47}As transistor channels) to have indium content higher than 53%. This is because the barrier layer must be substantially lattice matched to the transistor channel at the surface of the barrier layer where the transistor channel is formed. If there is a lattice mismatch, defects may form which can render the transistor channel ineffective.

For example, with an In_{0.53}Ga_{0.47}As transistor channel on a InAlAs barrier layer, transistor channels may be formed having a height “H” (see FIG. 2) of about 10 nm to 100 nm (or even greater). Thus, with an ever increasing need to increase the performance and density of transistors, which can be achieved with an increase transistor channel height, an In_{0.53}Ga_{0.47}As transistor channel on an InAlAs barrier layer can be used. However, a transistor channel of In_{0.70}Ga_{0.30}As formed on an InAlAs barrier layer cannot have a height H (see FIG. 2) greater than about 13 nm without defects rendering the transistor channel substantially unsuitable. Furthermore, a transistor channel of InAs formed on an InAlAs barrier layer cannot have a height H (see FIG. 2) greater than about 5 nm without defects rendering the transistor channel substantially unsuitable. Thus, high content indium materials are not a suitable transistor channel material, without a lattice matching barrier layer.

In one embodiment of the present description shown in FIG. 4, a lattice matched barrier layer has been found for the high content indium transistor channel materials, which will allow for the formation of effective transistor channels. In this embodiment, the high content indium content material may include InₓGa₍₁₋ₓ₎As, where x may be greater than 0.53 to 1.

FIG. 4 is a graph illustrating a grading path of an embodiment of the present description. Beginning with a substrate 102 (see FIGS. 1 and 2) made of silicon (element “Si”), the buffer layer 104 (see FIGS. 1 and 2) grades from the silicon to gallium arsenide (“GaAs”) along line 202. Gallium arsenide has about the same lattice parameter aluminum arsenide (see dashed line 204). Thus, the barrier layer 106 may begin as aluminum arsenide (“AlAs”) that can be graded (shown as line 206) toward aluminum antimony (“AlSb”) along the grading line between AlAs and AlSb demarked with white dots (i.e. along AlAs₍₁₋ₓ₎Sbₓ where x=0 to 1). In the grading, antimony displaces the arsenic to about 80% (e.g. AlAs_{0.20}Sb_{0.80}), where the lattice parameter is about the same as the lattice parameter of InAs (e.g. about 6.05), as shown with dashed line 208. Thus, between about 60% (AlAs_{0.40}Sb_{0.60}) to 100% (AlSb) antimony content should have sufficient lattice matching for the formation of high height, high content indium transistor channels. Therefore, in one embodiment, a portion of the barrier layer 106 abutting the transistor channel 112 (see FIG. 2) may comprise AlAs₍₁₋ₓ₎Sbₓ where x is between about 0.60 and 1. For reference's sake, In_{0.53}Ga_{0.47}As would have a lattice parameter of about 5.85 to 5.90 in the graph of FIG. 4.

In one embodiment, the barrier 106 layer may be graded in layers. As shown, a first barrier layer 106a may be formed on the buffer layer 104, where the barrier layer 106a may be AlAs, which is substantially lattice matched to the buffer layer 104, such as a buffer layer having GaAs abutting the first barrier layer 106a. A second barrier layer 106b having a portion of the arsenic (As) displaced with antimony (Sb), for example AlAs_{0.80}Sb_{0.20}, may be formed on the first barrier layer 106a. A third barrier layer 106c having a larger portion of the arsenic (As) displaced with antimony (Sb), for example AlAs_{0.60}Sb_{0.40}, may be formed on the second barrier layer 106b. A fourth barrier layer 106d having a portion of the arsenic (As) displaced with antimony (Sb), for example AlAs_{0.40}Sb_{0.60}, may be formed on the third barrier layer 106c. A fifth barrier layer 106e having a portion of the arsenic (As) displaced with antimony (Sb), for example about AlAs_{0.20}Sb_{0.80}, may be formed on the fourth barrier layer 106d.

The combination of the layers (i.e. the first barrier layer 106a, the second barrier layer 106b, the third barrier layer 106c, the fourth barrier layer 106d, and the fifth barrier layer 106e) comprises the barrier layer 106. As previously discussed, the fifth layer barrier layer 106e of about AlAs_{0.20}Sb_{0.80}, should be sufficient lattice match for high indium content materials (e.g. InₓGa₍₁₋ₓ₎As, where x may be greater than 0.53 to 1).

The various barriers layers (i.e. the first barrier layer 106a, the second barrier layer 106b, the third barrier layer 106c, the fourth barrier layer 106d, and the fifth barrier layer 106e) can be formed by any technique known in the art, including but not limited to, chemical vapor deposition (“CVD”), physical vapor deposition (“PVD”), atomic layer deposition (“ALD”), and the like.

It is understood that there may be any number of layers formed in the barrier layer 106 and that the layers may include any percent of aluminum, arsenic, and antinomy that is appropriate for forming the graded barrier layer 106.

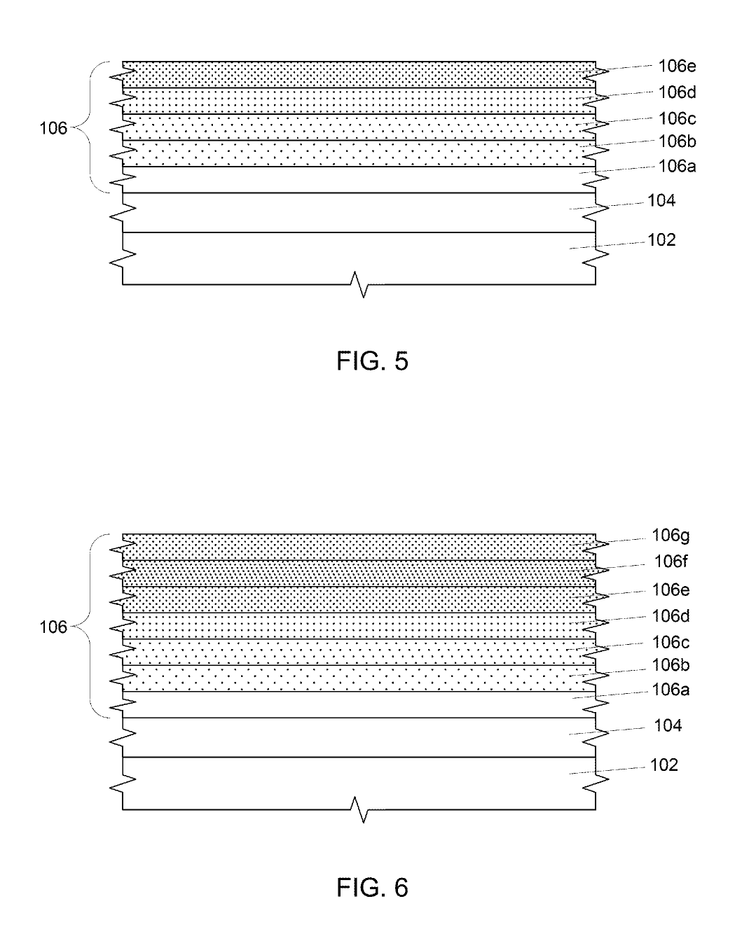

The formation of the barrier layer 106 in graded layers, as shown in FIG. 5, may be preferred, as the interfaces between the layers (e.g. the first barrier layer 106a, the second barrier layer 106b, the third barrier layer 106c, the fourth barrier layer 106d, and the fifth barrier layer 106e) may serve as defect termination areas, and, thereby, will be less likely to transfer defects to the subsequently formed transistor channel 112 (see FIG. 2), as will be understood by those skilled in the art.

In another embodiment shown in FIG. 6, the barrier layer 106 may include additional layers to take the necessary lattice matching to a higher level and then bring it back to a lattice match. For example, if AlAs_{0.20}Sb_{0.80} (e.g. barrier layer 106e) is a desired layer for the formation of an InAs layer for a transistor channel 112, an addition layer 106f may be formed of AlSb on the barrier layer 106e. A second additional barrier layer 106g may then be formed on the additional barrier layer 106f to grade back to the desired AlAs_{0.20}Sb_{0.80}. This non-linear grading may assist in reducing the potential of transferring defects to the transistor channel 112.

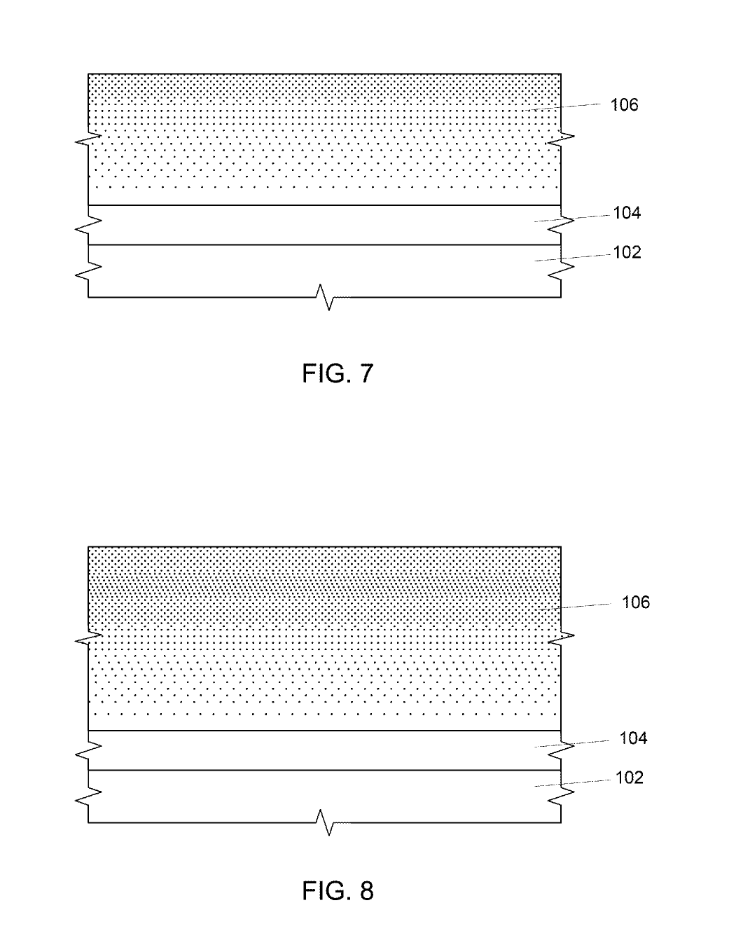

In still another embodiment illustrated in FIG. 7, the barrier layer 106 may be graded during the deposition process, wherein varying the deposition chemicals introduced during the deposition process to form a continuously graded, single layered barrier layer 106. In one example, the deposition may began with the introduction of aluminum and arsenic to form AlAs, which is substantially lattice matched to the buffer layer 104, such as a buffer layer having GaAs abutting the barrier layer 106. The introduced arsenic (As) may then be slowly displaced with introduced antimony (Sb) to gradually grade the barrier layer 106 to AlAs_{0.20}Sb_{0.80}. In FIG. 7, the concentration of antimony is represented in the density of the “black dots”.

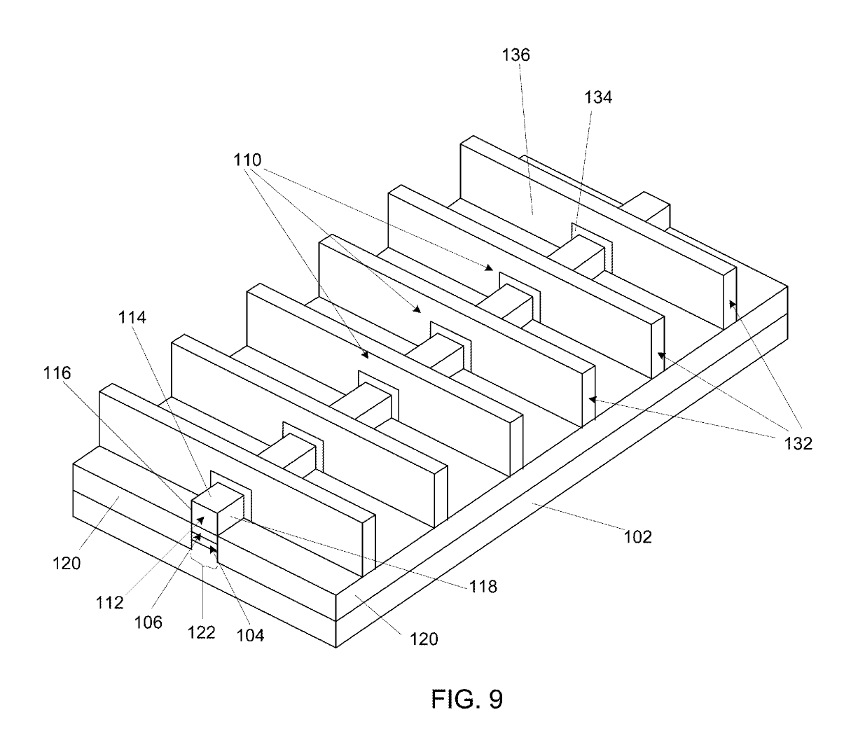

In still yet another embodiment illustrated in FIG. 8, the barrier layer 106 may be formed in a non-linear fashion by varying the deposition chemicals introduced during the deposition process, as described in FIG. 7, and by increasing the antimony content beyond a lattice matching amount during the deposition, then grading back to a lattice matching concentration, such as describe in FIG. 7.

One embodiment implementing the subject matter of the present description is illustrated in FIG. 9. FIG. 9 is a perspective view of a number of transistors 110 including a number gates formed on a transistor channel, which is formed on a substrate. In an embodiment of the present disclosure, the substrate 102 may be a monocrystalline silicon substrate or a silicon-on-insulator substrate having are a pair of spaced apart isolation regions 120, such as shallow trench isolation (STI) regions, which define the substrate active region 122 therebetween. The substrate 102, however, need not necessarily be a silicon monocrystalline substrate and can be other types of substrates, such as a germanium, a gallium arsenide, indium antimonide, lead telluride, indium arsenide, indium phosphide, gallium arsenide, gallium antimonide, and the like, any of which may be combined with silicon. The isolations regions 120 maybe be formed by forming trenches in the substrate 102 filling the trenches with an electrically insulative material, such as silicon oxide (SiO₂).

Each transistor 110, shown as tri-gate transistors, includes a transistor channel 112 disposed on the barrier layer 106, which is formed on the buffer layer 104 atop a portion of the substrate 102. The transistor channel 112 may have a top surface 114 and a pair of laterally opposite sidewalls, sidewall 116 and opposing sidewall 118. A portion of the buffer layer 104 abutting the substrate may be substantially lattice matched with the substrate 102. The barrier layer 106 may comprise AlAs₍₁₋ₓ₎Sbₓ where x is between about 0 and 1, and a portion of the barrier layer 106 abutting the buffer layer 104 may be substantially lattice matched with the buffer layer 104. The transistor channel 112 may be a high indium content transistor channel, as described above, and a portion of the barrier layer 106 abutting the high indium content transistor channel may be substantially lattice matched with the high indium content transistor channel. It is understood that any of the various embodiment for the buffer layer 104, the barrier layer 106, and the transistor channel 112 may be employed forming each transistor 110.

As further shown in FIG. 9, at least one gate 132 may be form over the transistor channel 112. A gate 132 may be fabricated by forming a gate dielectric layer 134 on or adjacent to the top surface 114 and on or adjacent to the pair of laterally opposing sidewalls 116, 118 of the transistor channel 112, and forming a gate electrode 136 on or adjacent the gate dielectric layer 134.

The gate dielectric layer 134 may be formed from any well-known gate dielectric material, including but not limited to silicon dioxide (SiO₂), silicon oxynitride (SiOₓN_{y}), silicon nitride (Si₃N₄), and high-k dielectric materials such as hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. The gate dielectric layer 134 can be formed by well-known techniques, such as by depositing a gate electrode material, such as chemical vapor deposition (“CVD”), physical vapor deposition (“PVD”), atomic layer deposition (“ALD”), and then patterning the gate electrode material with well-known photolithography and etching techniques, as will be understood to those skilled in the art.

As shown in FIG. 9, the gate electrode 136 may be formed on or adjacent to the gate dielectric layer 134. The gate electrode 136 can be formed by well-known techniques, such as by depositing a gate electrode material, such as chemical vapor deposition (“CVD”), physical vapor deposition (“PVD”), atomic layer deposition (“ALD”), and then patterning the gate electrode material with well-known photolithography and etching techniques, as will be understood to those skilled in the art.

The gate electrode 136 can be formed of any suitable gate electrode material. In an embodiment of the present disclosure, the gate electrode 136 may be formed from materials that include, but are not limited to, polysilicon, tungsten, ruthenium, palladium, platinum, cobalt, nickel, hathium, zirconium, titanium, tantalum, aluminum, titanium carbide, zirconium carbide, tantalum carbide, hafnium carbide, aluminum carbide, other metal carbides, metal nitrides, and metal oxides.

It is understood that a source region and a drain region (not shown) may be formed in the transistor channel 112 on opposite sides of the gate electrode 136. The source and drain regions may be formed of the same conductivity type, such as N-type or P-type conductivity.

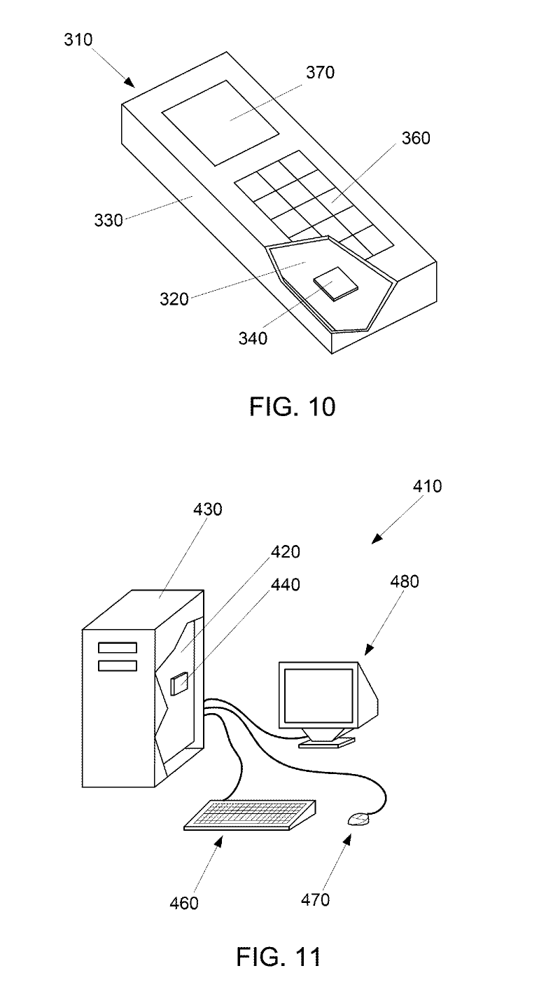

FIG. 10 illustrates an embodiment of a portable device 310, such as a cellular telephone or a personal data assistant (PDA), digital media player, of the like. The portable device 310 may comprise a substrate 320 within a housing 330. The substrate 320 may have various electronic components electrically coupled thereto including a microprocessor 340, such as a central processing units (CPUs), chipsets, graphics processor, ASICs, or other command/data processing device, having at least one transistor formed with a high indium content transistor channel, as described in the present description. The substrate 320 may be attached to various peripheral devices including an input device, such as keypad 360, and a display device, such an LCD display 370.

FIG. 11 illustrates an embodiment of a computer system 410. The computer system 410 may comprise a substrate or motherboard 420 within a housing 430. The motherboard 420 may have various electronic component electrically coupled thereto including a microprocessor 440, such as a central processing units (CPUs), chipsets, graphics processor, ASICs, or other command/data processing device, having at least one transistor formed with a high indium content transistor channel, as described in the present description. The substrate or motherboard 420 may be attached to various peripheral devices including inputs devices, such as a keyboard 460 and/or a mouse 470, and a display device, such as a monitor 480.

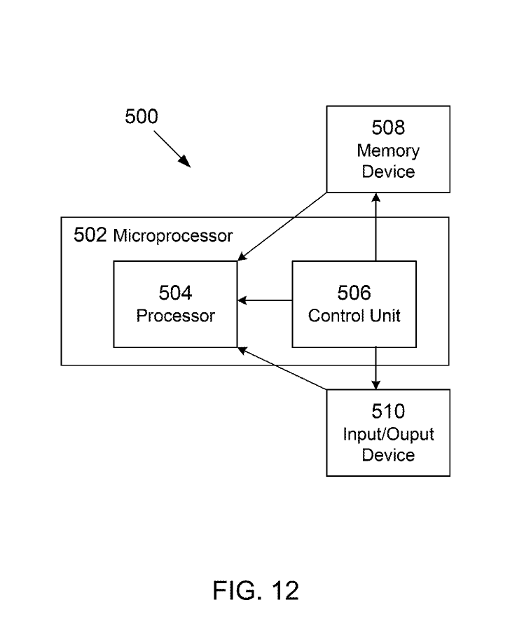

FIG. 12 illustrates a block diagram of an electronic system 500. The electronic system 500 can correspond to, for example, the portable system 310 of FIG. 10, the computer system 410 of FIG. 11, a process control system, or any other system that utilizes a processor and an associated memory. The electronic system 500 may have a microprocessor 502 (having a processor 504 and control unit 506), a memory device 508, and an input/output device 510 (it is, of course, understood that the electronic system 500 can have a plurality of processors, control units, memory device units and/or input/output devices in various embodiments). In one embodiment, the electronic system 500 may have a set of instructions that define operations which are to be performed on data by the processor 504, as well as, other transactions between the processor 504, the memory device 508, and the input/output device 510. The control unit 506 coordinates the operations of the processor 504, the memory device 508 and the input/output device 510 by cycling through a set of operations that cause instructions to be retrieved from the memory device 508 and executed. The processor 504 includes a plurality of transistors, wherein a least one of the plurality of transistor is formed with a high indium content transistor channel, as described in the present description.

It is also understood that the subject matter of the present description is not necessarily limited to specific applications illustrated in FIGS. 1-12. The subject matter may be applied to other microelectronic applications. Furthermore, the subject matter may also be used in any appropriate application outside of the microelectronic device fabrication field, as will be understood to those skilled in the art.

The detailed description has described various embodiments of the devices and/or processes through the use of illustrations, block diagrams, flowcharts, and/or examples. Insofar as such illustrations, block diagrams, flowcharts, and/or examples contain one or more functions and/or operations, it will be understood by those skilled in the art that each function and/or operation within each illustration, block diagram, flowchart, and/or example can be implemented, individually and/or collectively, by a wide range of hardware, software, firmware, or virtually any combination thereof.

The described subject matter sometimes illustrates different components contained within, or connected with, different other components. It is understood that such illustrations are merely exemplary, and that many alternate structures can be implemented to achieve the same functionality. In a conceptual sense, any arrangement of components to achieve the same functionality is effectively “associated” such that the desired functionality is achieved. Thus, any two components herein combined to achieve a particular functionality can be seen as “associated with” each other such that the desired functionality is achieved, irrespective of structures or intermediate components. Likewise, any two components so associated can also be viewed as being “operably connected”, or “operably coupled”, to each other to achieve the desired functionality, and any two components capable of being so associated can also be viewed as being “operably couplable”, to each other to achieve the desired functionality. Specific examples of operably couplable include but are not limited to physically mateable and/or physically interacting components and/or wirelessly interactable and/or wirelessly interacting components and/or logically interacting and/or logically interactable components.

It will be understood by those skilled in the art that terms used herein, and especially in the appended claims are generally intended as “open” terms. In general, the terms “including” or “includes” should be interpreted as “including but not limited to” or “includes but is not limited to”, respectively. Additionally, the term “having” should be interpreted as “having at least”.

The use of plural and/or singular terms within the detailed description can be translated from the plural to the singular and/or from the singular to the plural as is appropriate to the context and/or the application.

It will be further understood by those skilled in the art that if an indication of the number of elements is used in a claim, the intent for the claim to be so limited will be explicitly recited in the claim, and in the absence of such recitation no such intent is present. Additionally, if a specific number of an introduced claim recitation is explicitly recited, those skilled in the art will recognize that such recitation should typically be interpreted to mean “at least” the recited number.

The use of the terms “an embodiment,” “one embodiment,” “some embodiments,” “another embodiment,” or “other embodiments” in the specification may mean that a particular feature, structure, or characteristic described in connection with one or more embodiments may be included in at least some embodiments, but not necessarily in all embodiments. The various uses of the terms “an embodiment,” “one embodiment,” “another embodiment,” or “other embodiments” in the detailed description are not necessarily all referring to the same embodiments.

While certain exemplary techniques have been described and shown herein using various methods and systems, it should be understood by those skilled in the art that various other modifications may be made, and equivalents may be substituted, without departing from claimed subject matter or spirit thereof. Additionally, many modifications may be made to adapt a particular situation to the teachings of claimed subject matter without departing from the central concept described herein. Therefore, it is intended that claimed subject matter not be limited to the particular examples disclosed, but that such claimed subject matter also may include all implementations falling within the scope of the appended claims, and equivalents thereof.

What is claimed is:

1. A transistor comprising:
a buffer layer formed on a substrate, wherein a portion of the buffer layer abutting the substrate is substantially lattice matched with the substrate;
a barrier layer formed on the buffer layer, wherein the barrier layer comprises AlAs₍₁₋ₓ₎Sbₓ where x is between about 0 and 1, and wherein a portion of the barrier layer abutting the buffer layer is substantially lattice matched with the buffer layer; and
a high indium content transistor channel, wherein a portion of the barrier layer abutting the high indium content transistor channel is substantially lattice matched with the high indium content transistor channel.

2. The transistor of claim 1, wherein the portion of the barrier layer abutting the buffer layer comprises AlAs.

3. The transistor of claim 1, wherein the portion of the barrier layer abutting the high indium content transistor channel comprises AlAs₍₁₋ₓ₎Sbₓ where x is between about 0.60 and 1.

4. The transistor of claim 1, wherein the high indium content transistor channel comprises indium and arsenic.

5. The transistor of claim 4, wherein the high indium content transistor channel further comprises gallium.

6. The transistor of claim 1, wherein the high indium content transistor channel may comprise InₓGa₍₁₋ₓ₎As, where x is greater than 0.53 to 1.

7. The transistor of claim 1, wherein the high indium content transistor channel comprises AlAs_{0.20}Sb_{0.80} at the portion abutting the high indium content transistor channel, and wherein the high content transistor channel comprises InAs.

8. A transistor comprising:
a buffer layer formed on a substrate, wherein the buffer layer abutting the substrate is substantially lattice matched with the substrate;
a barrier layer formed on the buffer layer, wherein the barrier layer comprises an alloy of AlAs₍₁₋ₓ₎Sbₓ where x=0 to 1 and wherein a portion of the barrier layer abutting the buffer layer is substantially AlAs;
a high indium content transistor channel, wherein a portion of the barrier layer abutting the high indium content transistor channel is substantially AlAs₍₁₋ₓ₎Sbₓ where x=0.60 to 1; and
wherein the barrier layer is substantially graded between the portion abutting the buffer layer to the portion abutting the high indium content transistor channel.

9. The transistor of claim 8, the barrier layer comprises a plurality of layers, wherein each progressive layer from abutting the buffer layer has an increased concentration of antimony.

10. The transistor of claim 8, wherein the high indium content transistor channel comprises indium and arsenic.

11. The transistor of claim 10, wherein the high indium content transistor channel further comprises gallium.

12. The transistor of claim 8, wherein the high indium content transistor channel may comprise InₓGa₍₁₋ₓ₎As, where x is greater than 0.53 to 1.

13. The transistor of claim 8, wherein the high indium content transistor channel comprises AlAs_{0.20}Sb_{0.80} at the portion abutting the high indium content transistor channel, and wherein the high content transistor channel comprises InAs.

14. A transistor comprising:
a buffer layer formed on a substrate, wherein the buffer layer abutting the substrate is substantially lattice matched with the substrate;
a barrier layer formed on the buffer layer, wherein the barrier layer comprises an alloy of AlAs₍₁₋ₓ₎Sbₓ where x=0 to 1 and wherein a portion of the barrier layer abutting the buffer layer is substantially AlAs;
a high indium content transistor channel, wherein a portion of the barrier layer abutting the high indium content transistor channel is substantially AlAs₍₁₋ₓ₎Sbₓ where x=0.60 to 1; and
wherein the barrier layer is substantially non-linearly graded between the portion abutting the buffer layer to the portion abutting the high indium content transistor channel.

15. The transistor of claim 14, wherein the barrier layer comprises a portion of the barrier layer has a higher concentration of antimony than the portion of the barrier layer abutting the high indium content transistor channel.

16. The transistor of claim 14, the barrier layer comprises a plurality of layers, wherein at least one layer has a higher concentration of antimony than the portion of the barrier layer abutting the high indium content transistor channel.

17. The transistor of claim 14, wherein the high indium content transistor channel comprises indium and arsenic.

18. The transistor of claim 17, wherein the high indium content transistor channel further comprises gallium.

19. The transistor of claim 14, wherein the high indium content transistor channel may comprise InₓGa₍₁₋ₓ₎As, where x is greater than 0.53 to 1.

20. The transistor of claim 14, wherein the high indium content transistor channel comprises AlAs_{0.20}Sb_{0.80} at the portion abutting the high indium content transistor channel, and wherein the high content transistor channel comprises InAs.

21. A system, comprising:
a processor having a plurality of transistors formed on a semiconductor substrate, wherein each of the plurality of transistors comprises:
a buffer layer formed on a substrate, wherein a portion of the buffer layer abutting the substrate is substantially lattice matched with the substrate;
a barrier layer formed on the buffer layer, wherein the barrier layer comprises AlAs₍₁₋ₓ₎Sbₓ where x is between about 0 and 1, and wherein a portion of the barrier layer abutting the buffer layer is substantially lattice matched with the buffer layer; and
a high indium content transistor channel, wherein a portion of the barrier layer abutting the high indium content transistor channel is substantially lattice matched with the high indium content transistor channel.

22. The system of claim 21, wherein the portion of the barrier layer abutting the buffer layer comprises AlAs.

23. The system of claim 21, wherein the portion of the barrier layer abutting the high indium content transistor channel comprises AlAs₍₁₋ₓ₎Sbₓ where x is between about 0.60 and 1.

24. The system of claim 21, wherein the high indium content transistor channel comprises indium and arsenic.

25. The system of claim 24, wherein the high indium content transistor channel further comprises gallium.

26. The system of claim 21, wherein the high indium content transistor channel may comprise InₓGa₍₁₋ₓ₎As, where x is greater than 0.53 to 1.

27. The system of claim 21, wherein the high indium content transistor channel comprises AlAs_{0.20}Sb_{0.80} at the portion abutting the high indium content transistor channel, and wherein the high content transistor channel comprises InAs.
